(19) United States
(12) Patent Application Publication
(10) Pub. No.: US 2018/0116027 A1
(43) Pub. Date: Apr. 26, 2018

(54) LED MODULE FOR EMITTING WHITE LIGHT

(71) Applicant: TRIDONIC JENNERSDORF GMBH, Jennersdorf (AT)

(72) Inventor: Peter PACHLER, Graz (AT)

(73) Assignee: TRIDONIC JENNERSDORF GMBH, Jennersdorf (AT)

(21) Appl. No.: 15/567,308

(22) PCT Filed: Apr. 15, 2016
(86) PCT No.: PCT/AT2016/050099

§ 371 Date: Oct. 17, 2017

(30) Foreign Application Priority Data
Apr. 17, 2015 (DE) 10 2015 206 972.9

(51) Int. Cl. H05B 33/08; H01L 25/075; H01L 33/48

(52) U.S. Cl. CPC H05B 33/0857; F21Y 2113/13; H01L 33/486; H01L 25/0753

(57) ABSTRACT

The invention relates to an LED module (10, 10′, 10″) for emitting mixed light, preferably white light, comprising: a module plate (11) having at least one ridge (12) which delimits a light field (13), wherein a plurality of LED chips (14, 14′, 14″, 14′″) embedded in a casting compound (15) are arranged within the at least one light field (13); and wherein a fluorescent substance or a mixture of fluorescent substances (16, 17) is arranged selectively in the region around a respective LED chip (14, 14′, 14″, 14′″). The invention further relates to a method for producing such an LED module (10, 10′, 10″) and to a lighting device having such an LED module (10, 10′, 10″).

### FIELD OF THE INVENTION

The present invention relates to an LED module (light-emitting diode module) and a method for producing such an LED module for emitting light from a plurality of different light sources, which are preferably mixed to form white light. Furthermore, the present invention relates to a lighting device comprising at least one such LED module.

### BACKGROUND

LED modules suitable for emitting white light are known from the prior art. Said LED modules generally comprise a light-emitting light field formed by a combination of individual light points. The individual light points are designed to emit different light spectra. By way of example, blue light, red light and yellow light generated by a phosphor are emitted by the light points. The light points are typically formed by a so-called glob-top method. Furthermore, so-called SMD components are known, as implemented in the Philips product HUE, for example, in which dispensing drops are applied directly on the individual LED chips.

However, such LED modules have a relatively large light field in comparison with non-controllable light sources and moreover the light has to be homogenized in a mixing chamber, which requires additional structural space and which has the effect that luminaires require a reflector of insufficient size for the esthetic demands. Such light fields, if they are intended to be produced cost-effectively and with high efficiency, typically have a diameter of at least 19 mm (assuming a luminous flux of approximately 2000+lm), wherein with the known glob-top methods it is not possible, in principle, to further reduce the diameter of the light field if a sufficiently large light emission area is intended to be provided.

Furthermore, DE 20 2014 103 029 U1, for example, discloses LED modules having light fields which comprise differently embodied areal regions for emitting different light spectra. Said areal regions are separated here from the further areal regions in each case by dams or partitions. LED chips or LED strings are arranged in the regions separated in each case by the dams and are covered with a potting compound containing a phosphor or a phosphor mixture. The potting compounds here comprise different phosphors or different phosphor mixtures, such that the regions can emit the desired different light spectra that are necessary in order that a corresponding mixed light can be provided by the LED module. Here the dams between the areal regions have to have a certain minimum height and a certain minimum width in order to prevent an overflow and hence mixing of the different potting compounds. A homogeneous (mixed) light impression can be provided all the better here, the greater the number of separate areal regions provided. In the case of such embodiments, however, it can be disadvantageous here that the dams require a comparatively large area of the light field and this area accordingly is no longer available as light emission area.

In light of this prior art, it is an object of the present invention to provide an LED module and a method for producing an LED module for emitting mixed light, preferably a (mixed) white light, which improves the known prior art. In particular, the intention is to be able to provide LED modules which, owing to the dictates of production, no longer require dams in the light field, such that as far as possible the entire area of the light field is available as light emission area.

This object and other objects that are also mentioned or may be recognized by the person skilled in the art during the reading of the following description are achieved by the subject matter of the independent claims. The dependent claims develop the central concept of the present invention in a particularly advantageous manner.

### SUMMARY

An LED module according to the invention for emitting mixed light, preferably white light, comprising at least:

a module plate with at least one dam which delimits at least one light field, wherein a plurality of LED chips embedded in a potting compound are arranged within the at least one light field; and

wherein a phosphor or a phosphor mixture is arranged selectively in the region around a respective LED chip. Selectively, thus means that the concentration of the phosphor or of the mixture is greater around the LED chip and on the top side thereof than in the central region between the chips.

In other words, the present invention proposes that the phosphor is no longer distributed more or less homogeneously within a light field demarcated by a dam, or within a partial region of a light field that is demarcated by a dam, rather that each LED chip is selectively provided with a corresponding phosphor. Consequently, it is no longer necessary for the respective LED chips or the different areal regions to be separated from one another by dams within the light field. Consequently, either the area saved can be available as further light emission area or the size of the light field can be correspondingly reduced without losses in performance.

A phosphor here is generally a substance which is excitable by light that can be emitted by the LED chips used, and which thereupon emits a secondary light spectrum. Preferably, in the present invention, use is made of inorganic phosphors or else a quantum dot, for example ZnS, ZnSe, CdS, CdSe, ZnTe, CdTe. Preferably, the phosphor emits secondary light from the yellow, green and/or red spectral range if the excitation is effected by blue light; with the use of deep-blue light (<420 nm) or UV light, an emission of blue light is also required. Further phosphors that can be used in the present case are for example: silicates (Ca₃Sc₂Si₃O₁₂: Ce3+), orthosilicates (B.O.S.E.: e.g. (Ba, Sr, Ca)₂SiO₄:Eu²⁺, (Ba, Sr)₂SiO₄:Eu²⁺, (Ba, Ca)₂SiO₄:Eu²⁺, (Sr, Ca)₂SiO₄:Eu²⁺), garnets (YAG: Ce³⁺, (YGd)AG: Ce³⁺, LuAG: Ce³⁺), oxides (CaScO₂: Eu²⁺), SiALONs (a-SiALON: Eu²⁺, b-SiALON: Eu²⁺), nitrides (La₃Si₆N₁₁: Ce³⁺, CaAlSiN₃: Ce³⁺), oxynitrides (SrSi₂N₂O₂: Eu²⁺, (Ca,Sr,Ba)Si₂N₂O₂: Eu²⁺).

The present invention here understands light from the red light spectrum to be light having a peak wavelength of between approximately 580 and 670 nm, light from the blue light spectrum to be light having a peak wavelength of between approximately 390 and 480 nm, light from the green light spectrum to be light having a peak wavelength of between approximately 480 and 560 nm, and light from the yellow light spectrum to be light having a peak wavelength of between 560 and 630 nm.

Advantageously, the potting compound is a silicone- and/or epoxy-based potting compound which, in the spectral ranges that are important for the function, is totally transparent preferably already in the liquid state and preferably at least in the crosslinked state. Furthermore, it is preferred for the liquid potting compound itself not to contain a phosphor that is excitable by the light emitted by the LED chips. However, the potting compound may additionally comprise scattering particles for more homogeneous light intermixing.

It is preferred for LED chips that emit a blue light spectrum to be arranged in the at least one light field, wherein it is furthermore preferred for only LED chips that emit a blue light spectrum to be arranged in the at least one light field. Green, yellow or red phosphor or a mixture thereof can be arranged here on said LED chips or at said LED chips. An arrangement of only blue LED chips in the light field is particularly preferred in order to provide a so-called two-channel light field, that is to say a light field with which two spectra (for example a green and a red spectrum) can be provided and mixed. Moreover, it may be preferred for LED chips that emit a blue light spectrum to be provided only in specific regions of the at least one light field.

Furthermore, it is preferred for LED chips that emit a red or blue light spectrum to be arranged in the light field. Here, too, green, yellow or red phosphor or a mixture thereof can be arranged on said LED chips or at said LED chips. In this case, it is preferred for only the blue LED chips to be provided with a green, yellow or red phosphor and for no phosphor or no phosphor that is not excited by a red light spectrum to be applied at the red LED chips. An arrangement of blue and red LED chips in the light field is particularly preferred in order to provide a so-called three-channel light field, that is to say a light field with which three spectra (for example a red, a green and a yellow spectrum) can be provided and mixed.

In this context it should be pointed out that the present invention is not restricted to a specific LED chip/phosphor color combination. Rather, each LED chip can be provided with a desired and suitable phosphor in order to be able to provide a corresponding mixed light. The LED chips can comprise for example blue-luminous LED chips, red-luminous LED chips, green-luminous LED chips, yellow-luminous LED chips or LED chips that are luminous in the UV range. The emitted light spectrum can arise here as a result of an interplay between the respective LED chips and the phosphor arranged in the potting compound at or around the LED chip, or be generated directly by an LED chip. Consequently, red, green, yellow, green-yellow or white light having various white shades can be emitted by the LED chips or by the LED chip/phosphor combinations.

Advantageously, the LED chips are arranged as so-called LED strings in the at least one light field, wherein in this case it is furthermore preferred that above the LED chips of a respective LED string the same phosphor or the same phosphor mixture is applied on the potting compound. The LED strings here are preferably drivable separately or in interconnected groups (depending on the number of LED strings used). Consequently, by way of example, LED strings provided for emitting a first light spectrum and LED strings provided for emitting a second light spectrum can be interconnected with one another in each case in groups. As a result, it is possible to set and emit an arbitrary mixed light in the range between the first and second light spectra. The LED chips or the LED strings of the light field can preferably be drivable individually or jointly in such a way that their luminous color is variable by means of the driving. Furthermore, each LED string or each interconnected group of LED chips or LED strings can be dimmed individually, for example by means of pulse width modulation.

Preferably, the dam (or the dams) has a width as seen in plan view of between 50 μm and 2 mm, particularly preferably between 300 μm and 1.5 mm, and more preferably between 500 μm and 1000 μm. The dam is formed here either directly, on the module plate, for example by a suitable material being applied and cured (by a so-called dispensing method), or the dam is firstly produced as a separate component that is subsequently connected to the module plate. Furthermore, it is preferred for the dam to be embodied with a principally diffusely reflective white surface or with a specular reflective metallic surface.

Advantageously, no more further dams are provided within the at least one light field resulting from the at least one enclosing dam. However, a plurality of light fields delimited by a dam in each case can also be provided on the module plate.

Preferably, the light field encompassed by the at least one dam is circular and preferably has a luminous flux density of >5 lm/mm2, which results in a diameter of the light field of approximately 23 mm for a luminous flux packet of 2000 lm. However, the applied invention makes it possible to achieve a luminous flux density of 10 lm/mm2 to 20 lm/mm2, which leads to a light field diameter of approximately 16 mm to approximately 11 mm for a luminous flux packet of 2000 lm.

Advantageously, the LED module can furthermore dispense with the use of a light scattering screen. The arrangement of a light scattering screen may nevertheless be advantageous in specific cases. The light scattering screen imparts to the LED module an even more homogeneous color impression, that is to say that the mixing of the different light spectra that are emitted by the light field is improved once again by the scattering of the light. Furthermore, a so-called mixing chamber can be provided between the light field and the light scattering screen. The mixing chamber is preferably designed to achieve an effective intermixing of the different light spectra that are emitted by the light field. To that end, by way of example, optical elements such as lenses or reflectors can be provided in the mixing chamber. However, the mixing chamber can also be a solid block composed of a material having a high refractive index, for example of 1.5 or more. Overall, what is achieved by the mixing chamber and the light scattering screen together is that the individual light spectra that are emitted by the light field are no longer distinguishable by an observer of the LED module but rather appear as homogeneous mixed light, preferably homogeneous white light.

It is preferred here for one of the light spectra to have at least one peak in the range of between 520 and 580 nm. Furthermore, it is preferred for one of the light spectra to have at least two peaks, wherein one peak preferably lies in the range of between 520 and 580 nm and one peak preferably lies in the range of between 580 and 650 nm. Furthermore, a light spectrum having a plurality of peaks (for example 455 nm, 520 nm and 630 nm) can be emitted.

Preferably, the LED chips and the phosphors are chosen such that the light field is suitable for emitting white light having at least two different color temperatures, such that for example white light having different color temperatures can be emitted (for example so-called cold- and/or warm-white spectra). It is preferred here for a first color temperature to be in the range of between 5000 K and 1800 K and a second color temperature to be in the range of between 10 000 K and 2500 K. By its nature, the Planckian locus, on which the white color loci lie by definition, can be well adjusted with straight lines only in relatively close color temperature ranges; for this reason, color temperature ranges of 6000 K to 3000 K, 4000 K to 3000 K or 2700 K to 1800 K are preferred ranges for adjusting for example a daylight profile, a continuous switchover between customary interior lighting systems or the dimming of an incandescent bulb.

A method according to the invention for producing an LED module for emitting mixed light, preferably white light, comprises at least the following steps: providing a module plate with at least one dam which delimits at least one light field, wherein LED chips are arranged within the at least one light field; applying a liquid potting compound on the light field in such a way that the LED chips are covered by the potting compound; applying a phosphor assigned to at least one LED chip on the liquid potting compound selectively in a region vertically above the LED chip in such a way that the phosphor sinks in the liquid potting compound and remains in a region around and on the LED chip.

In other words, the present invention proposes firstly introducing a liquid potting compound into a light field demarcated by a dam. Afterward, above the individual LED chips, in each case a phosphor assigned to the respective LED chip is applied on the still liquid potting compound (preferably on the surface of the potting compound). The phosphor (i.e. the phosphor particles) subsequently falls in the potting compound and settles here on the surface of the LED chip and, if appropriate, in direct proximity (maximally 50%, preferably 30%, of the LED chip dimensioning in the plan view) of the LED chip on the bottom of the light field. The phosphor can subsequently be fixed in this position by the curing of the potting compound.

At a distance of 150%, preferably 100%, more preferably 50%, of the corresponding chip dimensioning in the plan view, the phosphor concentration is thus preferably less than 20%, more preferably 10%, even more preferably 5%, even more preferably 2%, of the average phosphor concentration on the top side of the LED chip.

Thus, given a chip edge length in the x-axis or y-axis (plan view of the chip from above) of 1 mm (as an example), “100%” means an adjacent edge of 1 mm.

Depending on the application, it may also be advantageous here for mixing regions (i.e. regions at which phosphor or different LED chips is arranged) with corresponding transverse excitation to arise between the individual LED chips. If said transverse excitation is undesired, that can be counteracted by the apportioning of the phosphor, by the spacing-apart of the LED chips or by adapted phosphor mixtures.

Moreover, by means of the apportioning of the phosphor and by means of an exact alignment of the phosphor application (as centrally as possible above the respective LED chip), it is possible to ensure that the phosphor covers only the respective LED chip and does not sink into adjacent regions onto the bottom of the light field, such that the formation of mixing regions could also be correspondingly minimized.

Consequently, the method according to the invention affords the possibility of arranging different phosphors or different phosphor mixtures selectively at the respective LED chips, without the need to separate the respective LED chips or the different areal regions from one another by dams within the light field. Consequently, either the area saved can be available as further light emission area or the size of the light field can be correspondingly reduced without losses in performance.

Preferably, the phosphor as liquid with phosphor particles dispersed therein is applied on the liquid potting compound. However, it is also possible to apply or sprinkle the phosphor as phosphor powder onto the liquid potting compound.

It is particularly preferred to apply both the liquid potting compound and the phosphor in liquid form by means of a dispensing method. A dispensing method is particularly well suited in the present case since liquid media can be relatively accurately apportioned and positioned by said method. If the phosphor is dispensed in the form of liquid drops, it is preferred for the liquid drops to have a diameter of between 0.5 mm and 5 mm, preferably between 1 mm and 4 mm, and particularly preferably between 2 mm and 3 mm. It has been found that with these sizes of drops, firstly, it is possible to perform a comparatively accurate positioning with use of a dispensing method above the LED chips and, secondly, excessively large and possibly undesired mixing regions in which transverse excitations could occur can be avoided.

The present invention furthermore relates to a lighting device comprising at least one LED module described above.

### BRIEF DESCRIPTION OF THE DRAWINGS

A detailed description of the figures is given below, wherein:

FIG. 1 shows a schematic cross-sectional view of an LED module according to the invention after phosphor has been dispensed onto the surface of the potting compound;

FIG. 2 shows a schematic cross-sectional view showing an enlarged excerpt from FIG. 1;

FIG. 3 shows a schematic cross-sectional view corresponding to FIG. 2 after the sinking of the phosphor;

FIG. 4 shows a schematic plan view of a (2-channel) LED module according to the invention;

FIG. 5 shows a schematic plan view of a further (multi-channel) LED module according to the invention.

### DETAILED DESCRIPTION OF THE PREFERRED EMBODIMENTS

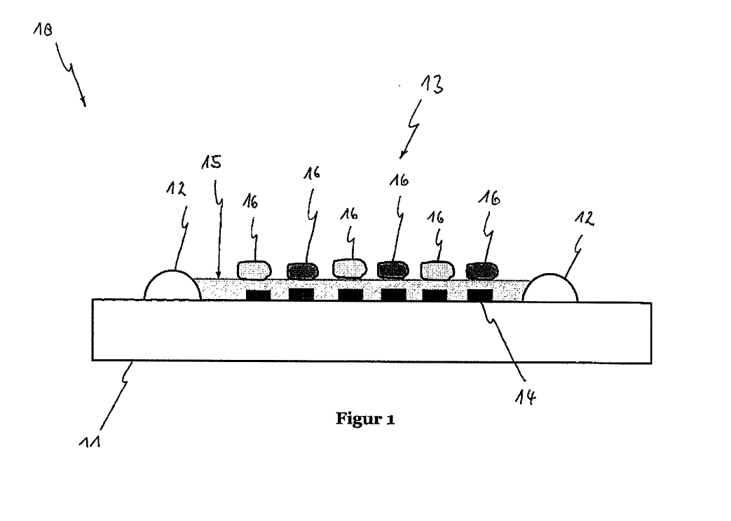

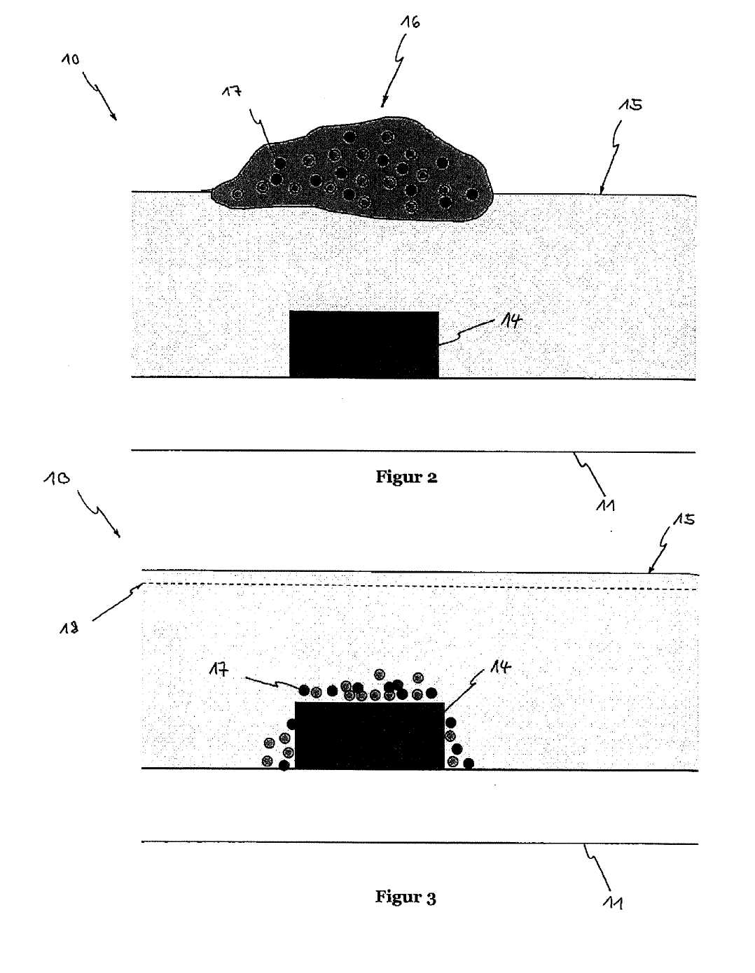

Firstly, a preferred method for producing an LED module 10 according to the invention is explained below with reference to FIGS. 1 to 3.

A first step involves providing a module plate 11 with a (at least one) dam 12, which preferably demarcates a substantially circular light field 13, and with LED chips 14 arranged within the light field 13.

Preferably, the dam 12 has a width as seen in plan view of between 50 gm and 2 mm. The dam 12 here can either be formed directly on the module plate 11 or firstly be produced as a separate component that is subsequently connected to the module plate 11.

The LED chips 14 can be for example blue-luminous LED chips 14, red-luminous LED chips 14, green-luminous LED chips 14, yellow-luminous LED chips 14 or LED chips 14 that are luminous in the UV range. In the embodiment shown in FIG. 1, structurally identical LED chips 14 are arranged in the light field 13, said LED chips preferably emitting a blue light spectrum. Green, yellow or red phosphor or a mixture thereof can be arranged on said LED chips or at said LED chips.

A further step involves introducing a liquid potting compound 15 in the region of the light field 13, specifically in such a way that the LED chips 14 are substantially completely covered with potting compound 15. The liquid potting compound 15 is preferably formed on a silicone and/or epoxy basis and is preferably transparent in the cured state. Furthermore, it is preferred for the liquid potting compound 15 not to contain phosphor that is excitable by the light emitted by the LED chips 14.

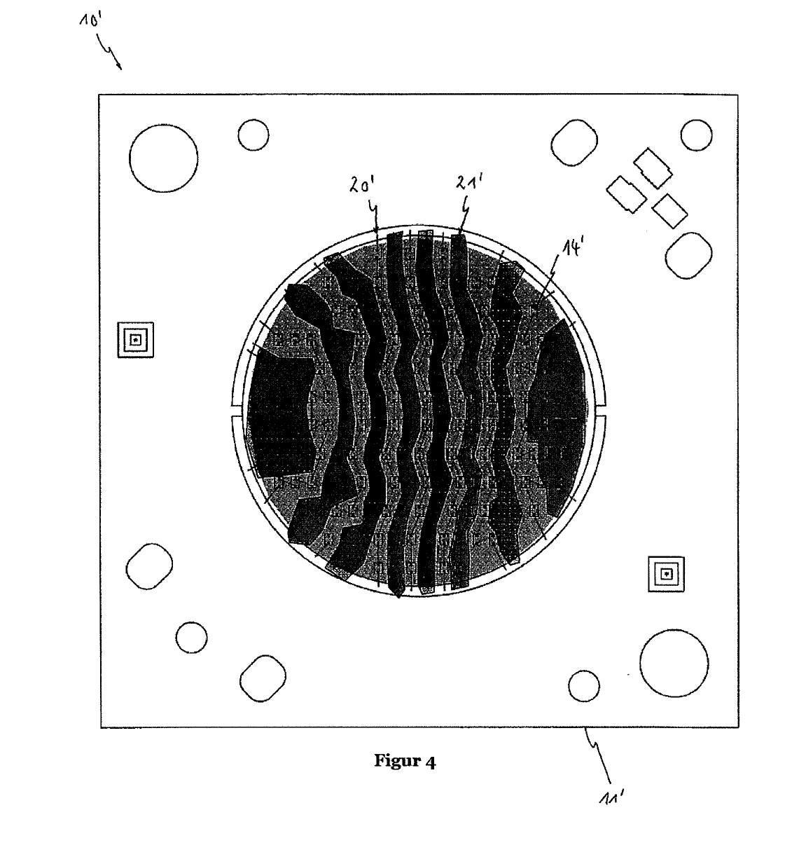

The next step involves applying phosphor, in the present case as liquid drops 16 with phosphor particles 17 dispersed therein, on the surface of the liquid potting compound 15. Advantageously, the liquid drops 16 here are likewise based on the same material as the liquid potting compound 15, in order that a composite assembly that is as homogeneous as possible can be provided during later curing. The liquid drops 16 here have approximately a diameter of 0.1 mm to 1.0 mm. During the introduction of the potting compound 15, it should furthermore be taken into consideration that the liquid drops 16 raise the liquid level within the light field 13. In FIG. 3, the raising of the liquid level on account of the dispensed liquid drops 16 is indicated by the dashed line 18.

As phosphor, use is preferably made of inorganic phosphors or a Q-dot (for example ZnS, ZnSe, CdS, CdSe, ZnTe, CdTe). Preferably, the phosphor emits secondary light from the yellow, green and/or red spectral range. Further phosphors that can be used in the present case are: silicates (Ca₃Sc₂Si₃O₁₂: Ce3+), orthosilicates (B.O.S.E.: e.g. (Ba, Sr, Ca)₂SiO₄:Eu²⁺, (Ba, Sr)₂SiO₄:Eu²⁺, (Ba, Ca)₂SiO₄:Eu²⁺, (Sr, Ca)₂SiO₄:Eu²⁺), garnets (YAG: Ce³⁺, (YGd)AG: Ce³⁺, LuAG: Ce³⁺), oxides (CaScO₂: Eu²⁺), SiALONs (a-SiALON: Eu²⁺, b-SiALON: Eu²⁺), nitrides (La₃Si₆N₁₁: Ce³⁺, CaAlSiN₃: Ce³⁺), oxynitrides (SrSi₂N₂O₂: Eu²⁺, (Ca,Sr,Ba)Si₂N₂O₂: Eu²⁺).

As shown in FIG. 3, on account of the gravitational force the phosphor particles 17 sink in the liquid potting compound 15 and deposit here on and at the LED chips 14, such that later they can be excited by the light emitted by the LED chips 14 and can emit a secondary light. Finally, the potting compound 15 with the phosphor particles 17 settled therein is cured, thus resulting in a solid composite assembly.

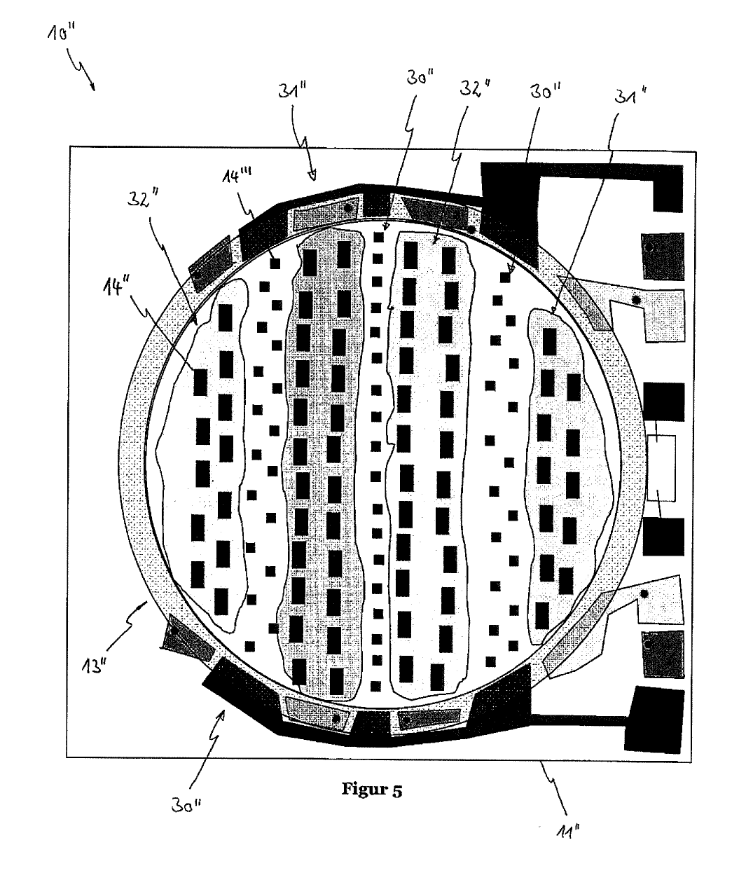

FIG. 4 shows one preferred embodiment of an LED module 10′ according to the invention. The LED module 10′ shown is a so-called two-channel variant (that is to say that two light spectra can be mixed with the LED module 10′, wherein only LED chips 14′ that emit blue light were used, on which either red or green phosphor, as described above, was applied.

The LED chips 14′ here are grouped as LED strings 20′, 21′ and interconnected with one another (in FIG. 4, in each case only one LED string 20′, 21′ is provided with a reference sign by way of example), wherein the LED chips 14′ provided with the same phosphor are interconnected with one another in each case as an LED string 20′ or 21′. A corresponding mixed light of a first and second light spectrum arises as a result of the two different phosphors (in the preferred embodiment shown, alternately green phosphor on the LED strings 20′ and red phosphor on the LED strings 21′). The LED strings 20′, 21′ are preferably drivable individually or jointly in such a way that their luminous color is variable by means of the driving. Furthermore, it is preferred that each LED string 20′, 21′ or each interconnected group of LED strings can be dimmed individually, for example by means of pulse width modulation. It should be noted that mixing regions arise or can arise between adjacent LED strings 20′, 21′ in the case of the embodiment shown in FIG. 4. If this is not desired, either it is possible to adapt the size of the drops during dispensing or the proportion of phosphor particles or it is possible to use phosphor mixtures adapted to one another.

FIG. 5 shows a further embodiment of an LED module 10″ according to the invention. The LED module 10″ shown here is a so-called three-channel variant (that is to say that three light spectra can be mixed by the LED module 10″).

In contrast to the embodiment shown in FIG. 4, in the present case LED chips 14″ that emit a blue light spectrum (indicated by the larger rectangular areas in FIG. 5) and LED chips 14′″ (indicated by the smaller rectangular areas in FIG. 5) that emit a red light spectrum are arranged in the light field 13″.

In the exemplary embodiment shown, no phosphor was arranged or dispersed above the red LED chips 14′″, whereas yellow and green phosphor were arranged or dispersed above the blue LED chips 14″. With the LED module 10″ shown in FIG. 5, a green light spectrum (by virtue of the blue LED chips 14″ and the green phosphor), a red light spectrum (directly by virtue of the red LED chips 14′″) and a yellow light spectrum (by virtue of the blue LED chips 14″ and the yellow phosphor) can thus be mixed or provided.

In the preferred embodiment shown, the light field 13″ thus comprises three red-emitting regions 30″, two yellow-emitting regions 31″ and two green-emitting regions 32″.

In a further embodiment, phosphor mixtures of yellow and green (orange) phosphors can be arranged or dispersed above the blue LED chips 14″. By way of example, these mixtures can contain different proportions of green and yellow phosphors. The light field 13″ thus exhibits a plurality of whitish-emitting regions 31″ having different hues or color temperatures.

The present invention is not restricted to the exemplary embodiments above, as long as it is encompassed by the subject matter of the following claims Furthermore, the exemplary embodiments above can be combined with and among one another in any desired way. In particular, all light fields described above are usable in an LED module described above, such that the respective explanations regarding the LED module or the respective light fields apply to all light fields, in principle, unless differences have been explicitly highlighted. Furthermore, it should be noted that the present invention is not restricted to a specific LED chip/phosphor color combination. Moreover, the present invention is not restricted to the case where all LED chips arranged in the light field are necessarily provided with phosphor.

1. An LED module (10, 10′, 10″) for emitting mixed light comprising:
a module plate (11) with at least one dam (12) which delimits at least one light field (13), wherein a plurality of LED chips (14, 14′, 14″, 14′″) embedded in a potting compound (15) are arranged within the at least one light field (13); and wherein a phosphor or a phosphor mixture (16, 17) is arranged selectively in the region around a respective LED chip (14, 14′, 14″, 14′″).

2. The LED module (10, 10′, 10″) as claimed in claim 1, wherein the potting compound (15) is a silicone-based, an epoxy-based or both silicone- and epoxy-based potting compound.

3. The LED module (10, 10′, 10″) as claimed in claim 1, wherein in the potting compound (15) phosphor (16, 17) is generally arranged only in a region around a respective LED chip (14, 14′, 14″, 14′″), and wherein the phosphor is an inorganic phosphor or a quantum dot.

4. The LED module (10, 10′, 10″) as claimed in claim 1, wherein only LED chips (14, 14′, 14″, 14′″) which emit a blue light spectrum are arranged in the at least one light field (13).

5. The LED module (10, 10′, 10″) as claimed in claim 1, wherein LED chips (14, 14′, 14″, 14′″) which emit a red or a blue light spectrum are arranged in the at least one light field (13).

6. The LED module (10, 10′, 10″) as claimed in claim 1, wherein a green, yellow or red phosphor or a mixture thereof is arranged in a region around an LED chip (14, 14′, 14″, 14′″) that emits a blue light spectrum.

7. The LED module (10, 10′, 10″) as claimed in claim 6, wherein different green, yellow or red phosphors or mixtures thereof are arranged in the regions around an LED chip (14, 14′, 14″, 14′″) that emits a blue light spectrum.

8. The LED module (10, 10′, 10″) as claimed in claim 1, wherein no phosphor, or no phosphor that is excitable by a red light spectrum, is arranged in a region around an LED chip (14, 14′, 14″, 14′″) that emits a red light spectrum.

9. The LED module (10, 10′, 10″) as claimed in claim 1, wherein the LED chips (14, 14′, 14″, 14′″) are arranged as LED strings (20′, 21′) in the at least one light field (13), and wherein a same phosphor or a same phosphor mixture is arranged in a region around a respective LED chip (14, 14′, 14″, 14′″) of an LED string (20′, 21′).

10. The LED module (10, 10′, 10″) as claimed in claim 1, wherein the at least one dam (12) has a width as seen in plan view of between 500 μm and 1000 μm, and wherein the at least one dam (12) is embodied as reflective, with a white or metallized surface.

11. The LED module (10, 10′, 10″) as claimed in claim 1, wherein no further dam is provided within the at least one light field (13).

12. The LED module (10, 10′, 10″) as claimed in claim 1, wherein the light field (13) encompassed by the at least one dam (12) is circular and provides a luminous flux density of greater than 5 lm/mm² and has a diameter of approximately 23 mm in the case of a luminous flux packet of 2000 lm; a luminous flux density of between 10 lm/mm2 and 20 lm/mm2 is provided and, preferably, a light field diameter of between approximately 16 mm and approximately 11 mm is provided in the case of a luminous flux packet of 2000 lm.

13. The LED module (10, 10′, 10″) as claimed in claim 1, wherein a light scattering screen is arranged at the at least one light field (13) in a manner spaced apart in the light emission direction, and wherein a mixing chamber is preferably provided between the light scattering screen and the at least one light field (13).

14. The LED module (10, 10′, 10″) as claimed in claim 13, wherein the mixing chamber is provided by a tubular element, which comprises a diffusing element at an exit end.

15. A lighting device, comprising at least one LED module (10, 10′, 10″) as claimed in claim 1.

16. A method for producing an LED module (10, 10′, 10″) for emitting mixed light comprising at least the following steps:
providing a module plate (11) with at least one dam (12) which delimits at least one light field (13), wherein LED chips (14, 14′, 14″, 14′″) are arranged within the at least one light field (13);
applying a liquid potting compound (15) on the at least one light field (13) in such a way that the LED chips (14, 14′, 14″, 14′″) are covered by the potting compound (15);
applying a phosphor (16, 17) assigned to an LED chip (14, 14′, 14″, 14′″) on the liquid potting compound (15) in a region above the LED chip (14, 14′, 14″, 14′″) in such a way that the phosphor sinks in the liquid potting compound (15) and remains in a region around the LED chip (14, 14′, 14″, 14′″).

17. The method as claimed in claim 16, wherein phosphor particles (17) dispersed in a liquid or matrix (16) are applied on the liquid potting compound (15), and wherein the liquid potting compound (15), the phosphor (16, 17), or both the liquid potting compound (15) and the phosphor (16, 17) are applied by a dispensing method.

18. The method as claimed in claim 16 wherein only LED chips (14, 14′, 14″, 14′″) which emit a blue light spectrum are arranged in the at least one light field (13).

19. The method as claimed in claim 16, wherein LED chips (14, 14′, 14″, 14′″) which emit a red or a blue light spectrum are arranged in the at least one light field (13).

20. The method as claimed in claim 19, wherein above the LED chips (14, 14′, 14″, 14′″) that emit a blue light spectrum, green, yellow or red phosphor or a mixture thereof is applied on the liquid potting compound (15), and wherein no phosphor, a phosphor that is not excited by a red light spectrum, or a combination thereof, is applied above the LED chips (14, 14′, 14″, 14′″) that emit a red light spectrum.
